(19) United States
(12) Patent Application Publication
(10) Pub. No.: US 2017/0098471 A1
(43) Pub. Date: Apr. 6, 2017

(54) METHODS AND APPARATUSES FOR LOW POWER STATIC RANDOM ACCESS MEMORY (SRAM) CELL AND ARRAY ARCHITECTURE FOR ABOVE, NEAR AND BELOW THRESHOLD VOLTAGE OPERATION

(71) Applicant: Richard Phillips, Ontario (CA)

(72) Inventor: Richard Phillips, Ontario (CA)

(73) Assignee: PLSense Ltd., Yokneam (IL)

(21) Appl. No.: 15/283,452

(22) Filed: Oct. 3, 2016

Related U.S. Application Data
(60) Provisional application No. 62/236,465, filed on Oct. 2, 2015.

(51) Int. Cl. G11C 11/419

(52) U.S. Cl. CPC G11C 11/419

(57) ABSTRACT

Circuits and methods for implementing a 10-T SRAM cell with independent read and write data ports, no data line precharge between cycles, and single-ended read and write access into the SRAM cell. The single ended nature of the cell and the elimination of a precharge period between accesses on both read and write ports saves considerable active power. This, in conjunction with the elimination of traditional column decode such that only the addressed SRAM cells are connected to their read or write data lines saves additional power while retaining reasonably high speeds, very good yield and enables the SRAM to operate in the voltage range that are near and below the threshold voltages of the MOSFET transistors.

### FIELD

This invention relates generally to the field of design of Semiconductor Integrated Circuit, and more specifically to a Near/Sub Threshold implementation for ultra-low power memory design.

### BACKGROUND OF THE INVENTION

As more electronic devices become smaller and handheld, battery life of these devices become more important. A large component of many battery powered integrated circuits is SRAM, so reducing the active (read and write) power of these memories will increase the battery life time. The dominant conventional power saving technique is through reduction of power supply voltage, so any low power memory solution must be able to work down to voltages near or below the threshold voltages of the MOSFET transistors that make up the CMOS integrated circuit. This work describes a novel storage cell and a method of its use to enable significant reductions in active power consumption over state of the art structures and techniques.

### BRIEF DESCRIPTION OF THE DRAWINGS

The invention may be understood by referring to the following description and accompanying drawings that are used to illustrate embodiments of the invention. In the drawings:

FIG. 1: illustrates example schematic of Six-Transistor (6-T) SRAM Cell from Prior Art;

FIG. 2: illustrates example schematic of Eight-Transistor (8-T) SRAM Cell from Prior Art;

FIG. 3: illustrates example schematic of a single row of Memory Array column decode for one bit from Prior Art;

FIG. 4: illustrates example schematic of Ten-Transistor (10-T) SRAM Cell from this invention;

FIG. 5: illustrates example schematic of a single row of the Memory Array block decode from this invention;

### PRIOR ART

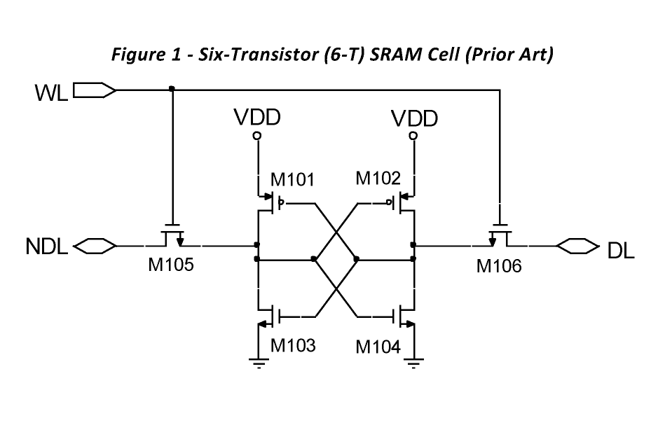

### Six-Transistor (6-T) SRAM Cell—FIG. 1

The standard SRAM cell for many years has been a six-transistors (6-T) circuit that uses a single port to perform both read and write operations. While it is the smallest of all SRAM circuits, it suffers from the fact that both read and write operations must be differential (which increases the active power by a factor of two) and that the data lines (DL and NDL in FIG. 1) must be precharged between cycles since the cell can only pull in one direction during reads, and requires three possible logic states during writes (write-1, write-0, or do nothing). Precharging also increases the statistical power of the SRAM by an additional factor of two when one considers the case of half the data not changing from cycle to cycle.

Since the 6-T SRAM cell uses the same differential port to perform both reads and writes (controlled by the same wordline signal, WL in FIG. 1), it becomes very difficult or impossible to correctly size the transistors to function in both roles over a wide supply range from the maximum allowed for the CMOS manufacturing process down to below the threshold voltage of the individual MOSFET transistors. Significant additional circuitry is needed around the SRAM cell array to control supply and signal lines to ensure basic functionality which adds to the area and active power consumption.

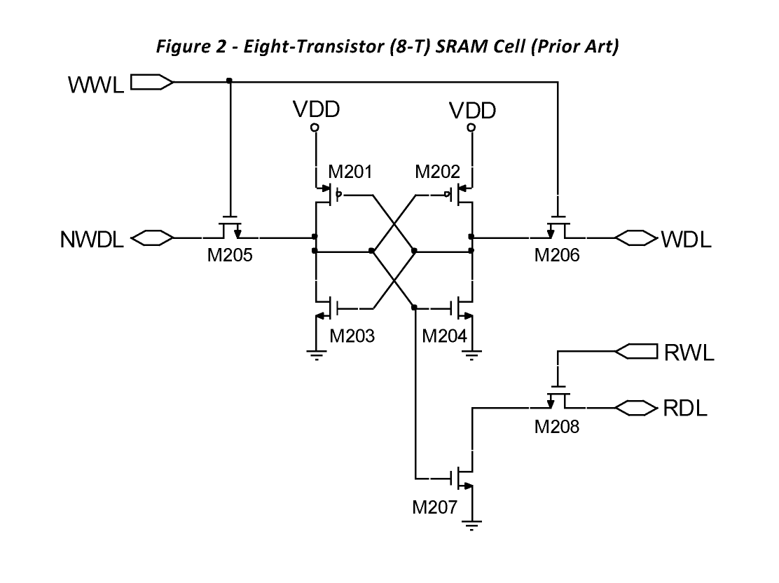

### Eight-Transistor (8-T) SRAM Cell—FIG. 2

To separate out the read and write functions of the SRAM cell the read and write ports are separated by the addition of two extra NMOS transistors and an extra dedicated read wordline (RWL in FIG. 2). This increases the operating margin of the cell over process and environmental conditions, but does nothing to address the differential, precharged write port requirements. Also, since the read port only drives negatively, it requires a read data line that is precharged high between cycles (RDL in FIG. 2).

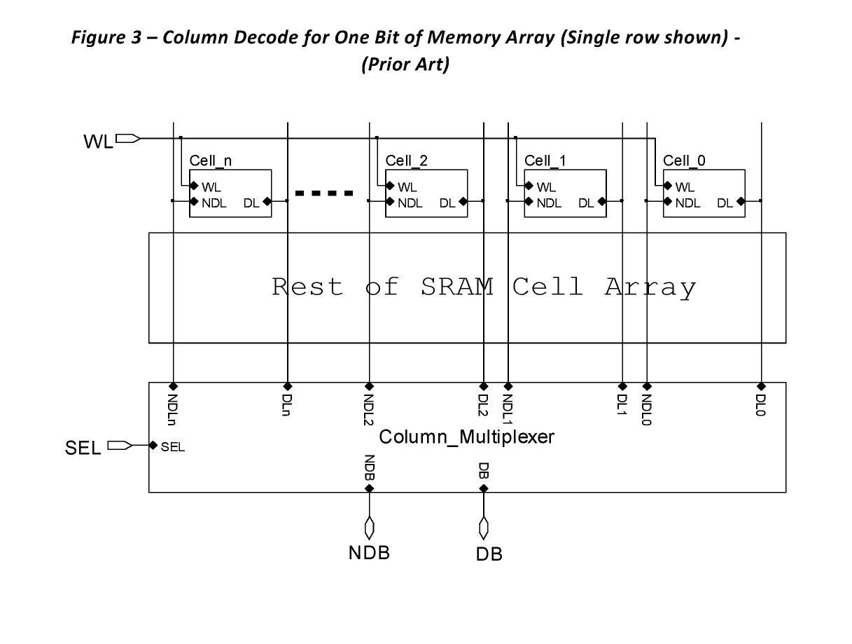

### Column Decode—FIG. 3

To allow for ease of modularity, SRAMs are usually built with a bit slice architecture where each data bit of the input/output word is stored in its own slice of the array. Since this bit slice array must be two dimensional (as opposed to a single column of possibly thousands of SRAM cells) there needs to be a column decode where multiple cells are accessed at once to achieve the read or write of the single cell one is addressing. In typical memories this column multiplexer can be 2, 4, 8, 16, 32, 64 (or more) cells wide. During read operations, in the case of a 16:1 column multiplexer this means that for every SRAM cell that is being read (as example Cell_0 in FIG. 3), an additional 15 SRAM cells are driving their data lines (as example Cell_1 to Cell_n in FIG. 3) with the resulting voltage being discarded by the deselected column multiplexer input (as seen in FIG. 3 all row cells from 0 to n are activated but only one is accessed). These 15 lines then have to be precharged at the end of the cycle (if precharge is used), or overdriven by opposite data the next time such data is read out onto those same lines (if precharge is not used), wasting an enormous amount of switching power.

During write operations, the 15 unselected data lines (DL1/NDL1 through DLn/NDLn outputs of the column multiplexer in FIG. 3, assuming that Cell_0 is being written) perform a dummy read since their wordline turns on but complementary write data are not driven onto their data lines. These then have to be precharged back to their initial (usually high) starting voltage, exhibiting the same large waste of power as is the case in a read operation

### DESCRIPTION OF INVENTION

To vastly reduce the power consumption limitations imposed by conventional 6-T and 8-T SRAM cells and their arrangement into an array with column decode, a new ten-transistors (10-T) SRAM cell is proposed which is implemented in an array that does not use conventional column decoding.

This invention may be used by any system which requires lower processing power with ultra-low power consumption.

This invention has been described as including various operations. Many of the processes are described in their most basic form, but operations can be added to or deleted from any of the processes without departing from the scope of the invention.

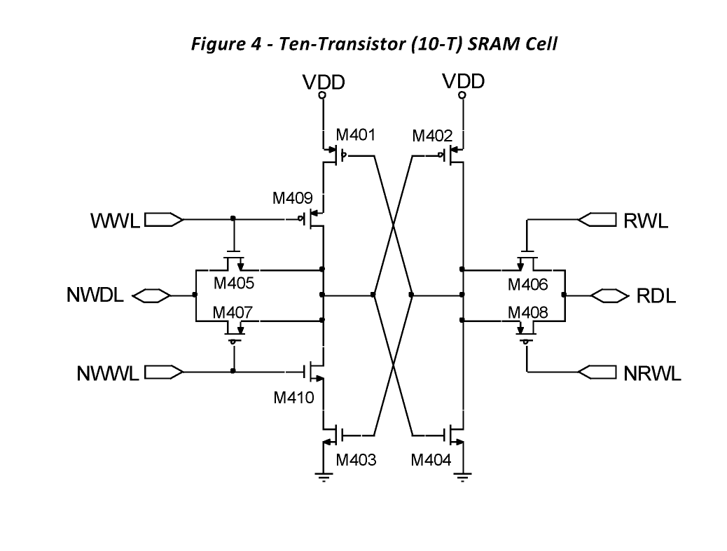

### Ten-Transistor (10-T) SRAM Cell—FIG. 4

To overcome the power limitations of the 6-T and 8-T SRAM cells we need an SRAM cell in which:
The read and write ports are separate so the voltage supply may be dropped to and below that of the threshold voltages of the contained MOSFETs and the two ports can be optimized independently.
Both read and write ports are single ended, not differential, such that the read and write switching power is reduced.
Both read and write data lines do not need to be precharged between memory cycles for correct functionality, to further reduce the read and write switching power.

The 10-T SRAM cell accomplishes this in the following ways:
The read and write ports (RDL and NWDL in FIG. 4) use separate wordlines (which access the cell), WWL/NWWL for the write and RWL/NRWL for the read as seen in FIG. 4 and data lines (which steer data in to and out of the cell). This is an SRAM cell with two separate ports which makes sizing of the access pass transistors and storage inverters independent for read and write operations.
Both read and write ports are single ended, thus avoiding the active power penalty associated with differential read or write access in more conventional SRAM cells.
Both read and write ports use complementary MOSFETS (both PMOS and NMOS) such that full “1” and “0” data can pass in to and out of the cell. During a read operation, a “0” on the read data line can be over-written by a “1” in the cell, and conversely a “1” on the read data line can be overwritten by a “0”. Consequently, no data line precharge is required along the entire read data path. Similarly, a “1” or “0” on the write data line can pass into the cell with no attenuation for a full write. As such no precharge is required along the entire write data path between cycles.

The MOSFETS M409 and M410 on FIG. 4 are added to completely turn off the feedback inverter on the write side of the SRAM cell, but are not essential for correct operation of a write. They are added here to reduce temporary DC currents flowing during the write operation as the data on the write data lines overdrives the feedback inverter in the cell (M401 and M403 in FIG. 4). This saves switching power during write cycles. They are also included because at small geometry process nodes where the power supply of the cell is close to or below the MOSFET threshold voltage, local variation makes the requirements of the feedback inverter lengths to be very large, to the point of the resulting 8-T cell (that of FIG. 4 minus M409 and M410) being larger than a 10-T cell shown built from all minimum geometry transistors. The 10-T cell has no such DC inverter overdrive currents, or size limitations placed on any of the write-side transistors. M409 will turn off when a “0” on the write data line (NWDL) is being written, thus blocking the counter-driving pull-up, M401 if the cell initially stores a “0” on the gate of M401. Conversely, M410 will turn off when a “1” on the write data line (NWDL) is being written, thus blocking the counter-driving pull-down, M403 if the cell initially stores a “1” on the gate of M403.

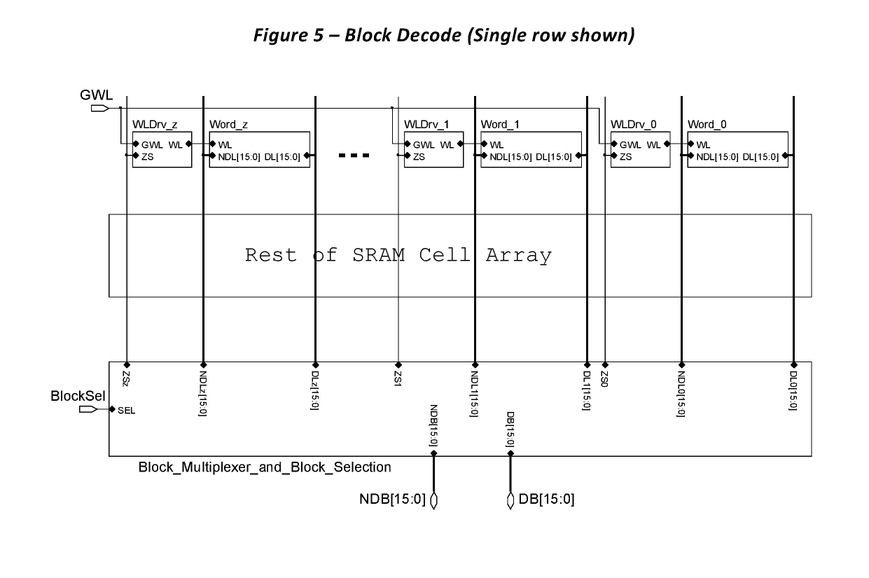

### Block Decode—FIG. 5

To eliminate the wasted power caused by discharging and re-charging of multiple unaddressed columns in a conventional column decode architecture, a block decoded array is used whereby a local wordline of only the accessed cells is turned on (one of the WL nodes in each block of cells across the array in FIG. 5). This requires a dedicated complementary local wordline driver for every word of the memory. Since each driver is a simple AND gate that decodes the row and block selection inputs, it can be small compared with the total SRAM cell area it drives. All blocks must be multiplexed together at the end of the data lines which adds some additional switching power due to the additional data line bussing, but not nearly enough to offset the savings due to the removal of the redundant SRAM cell accesses in an architecture that employs column decode (like the one at FIG. 3 which list the prior art).

By replacing the column decode with a block decode (the Block_Multiplexer_and_Block_Selection block in FIG. 5), we ensure that only the cells that are to be written have their wordline activated. This eliminates the additional design margin in the SRAM cells for those columns that are not selected during writes but have their wordlines activated—so-called half-accesses—as is the case with column decode schemes.

What is claimed is:

1. A method for designing a Static Random Access Memory (SRAM) circuit and architecture configuration comprising:
a ten-transistor (10-T) storage cell that operates with a dedicated single-ended non-precharged write port (with cell inverter feedback blocking);
a separate dedicated single-ended non-precharged read port;
arrayed without the use of column decode such that only the addressed cells have their corresponding read or write wordlines turned on for each read or write operation;
capable of working at voltage range that are near and below the threshold voltages of the MOSFET transistors.

2. A method according to claim 1, wherein said ten-transistor (10-T) static random access memory (SRAM) cell comprising:
a pair of back to back CMOS inverters to provide storage that are coupled to the read and write access ports;
a read output port (RDL);
a complementary pair of read wordline input ports (RWL, NRWL);
an inverted write input port (NWDL);
a complementary pair of write wordline input ports (WWL, NWWL);

3. A method according to claim 1, wherein said 10-T SRAM cell, static single-ended input data is passed into the SRAM cell from the inverted write input port (NWDL) when the complementary write wordline pair is turned on (WWL=1, NWWL=0).

4. A method according to claim 1, wherein said 10-T SRAM cell, static single-ended output data is passed from the SRAM cell to the read output port (RDL) when the complementary read wordline pair is turned on (RWL=1, NRWL=0).

5. A method according to claim 1, wherein said 10-T SRAM cell, the feedback path of the back-to-back CMOS inverters is broken by series PMOS and NMOS switches in the pull-up and pull-down path respectively of one inverter to permit the write operation to occur with no device ratioing required.

6. A method according to claim 1, wherein said 10-T SRAM cell, a single write data line (NWDL) is required to write both 0 and 1 polarities of digital data into the SRAM cell.

7. A method according to claim 1, wherein said 10-T SRAM cell, the single write data line (NWDL) is not required to be precharged between writes to a data-independent voltage for correct operation.

8. A method according to claim 1, wherein said 10-T SRAM cell, a single read data line (RDL) is required to read both 0 and 1 polarities of digital data from the SRAM cell.

9. A method according to claim 1, wherein said 10-T SRAM cell, the single read data line (RDL) is not required to be precharged between reads to a data independent voltage for correct operation.

10. A method according to claim 1, wherein said 10-T SRAM cell, that allows single-ended read operations with no intermediate precharge values on the read datapath in order to reduce the consumption of active read power.

11. A method according to claim 1, wherein said 10-T SRAM cell, that allows single-ended write operations with no intermediate precharge values on the write datapath in order to reduce the consumption of active write power.

12. An array of SRAM cells that are organized in a manner such as not to require column data line multiplexing between accessed columns on either read or write data lines.

13. A method according to claim 12, wherein said array of SRAM cells whereby only those cells in the array that are to be read or written are accessed by the read or write word lines in order to reduce the consumption of both read and write active powers.
